(19) United States
(12) Patent Application Publication
(10) Pub. No.: US 2026/0058845 A1
(43) Pub. Date: Feb. 26, 2026

(54) METHOD AND SYSTEM TO PERFORM CHANNEL ESTIMATION IN NARROWBAND NON-TERRESTRIAL NETWORKS USING DATA AIDING

(71) Applicant: Samsung Electronics Co., Ltd., Gyeonggi-do (KR)

(72) Inventor: Raul Hernan ETKIN, Sunnyvale, CA (US)

(21) Appl. No.: 18/977,202

(22) Filed: Dec. 11, 2024

Related U.S. Application Data
(60) Provisional application No. 63/686,367, filed on Aug. 23, 2024.

(51) Int. Cl. H04L 25/02; H03M 13/09; H03M 13/41

(52) U.S. Cl. CPC H04L 25/024; H03M 13/09; H03M 13/4146; H04L 25/0224

(57) ABSTRACT

A system and a method are disclosed for performing channel estimation in a communication system. The method includes receiving, based on one or more repetitions of a transmitted signal, pilot resource elements (REs); determining at least two sets of partial accumulations of scrambled data REs over the one or more repetitions; generating one or more log-likelihood ratios (LLRs) based on a preliminary channel estimate derived from the pilot REs and the partial accumulations of scrambled data REs; generating a secondary channel estimate based on the one or more LLRs; and decoding data using the secondary channel estimate based on the one or more LLRs.

### CROSS-REFERENCE TO RELATED APPLICATION

This application claims the priority benefit under 35 U.S.C. § 119 (c) of U.S. Provisional Application No. 63/686,367, filed on Aug. 23, 2024, the disclosure of which is incorporated by reference in its entirety as if fully set forth herein.

### TECHNICAL FIELD

The disclosure generally relates to channel estimation (CE) techniques for wireless communication systems. More particularly, the subject matter disclosed herein relates to improvements to iterative data-aided CE in narrowband non-terrestrial networks (NB-NTNs), utilizing structures of scrambled signals to enhance performance under low signal-to-noise ratio (SNR) conditions.

### SUMMARY

NB-NTN communication protocols have been defined by the third Generation Partnership Project (3GPP) for NTNs, such as satellite communication systems. These protocols are designed for low data rate communications and operate with weak signals, using NB frequency allocations to achieve reliable communication despite the path loss between satellites and a user equipment (UE).

CE in NB-NTN may be performed using predefined training sequences, or pilots, which are known in advance to the receiver. Pilots are part of the protocol overhead and do not carry any user data, meaning they only occupy a small portion of the resource elements (REs) in the protocol. In satellite communications, where signal levels are often low, relying on pilots for CE can result in noisy channel estimates, which can degrade overall communication performance.

To improve CE, filtering techniques like moving average (MA) filters, Kalman filters, or Kalman smoothers can be applied to the pilot REs, but these approaches are limited by the number of pilots available and by the variability of the channel over time and frequency. Consequently, alternative CE methods that use other information in addition to pilots are often necessary. One such method involves using previously decoded data to generate virtual pilots, which are then used to assist in CE. However, the effectiveness of this approach depends on the accuracy of the decoded data and the proximity (in time and frequency) of the data to the REs where CE is needed. As the time or frequency separation increases, the virtual pilots become less useful, especially in channels that change over time and frequency.

NB-NTNs differ from terrestrial networks (TNs) in several aspects that affect CE performance. NB-NTN typically operates with lower SNRs, uses NB frequency allocations, experiences less scattering, and has smaller Doppler spreads but larger Doppler shifts due to the movement of satellites. Therefore, CE routines (e.g., algorithms) should be adapted to handle these unique characteristics to ensure effective performance.

Because of the low SNR, NB-NTN systems may rely on repeated transmissions of the same codeword to lower the effective code rate and improve the reliability of communication. The present disclosure leverages these repeated transmissions to develop and evaluate low-complexity iterative detection and decoding (IDD) CE routines. These routines may use soft information, such as log-likelihood ratios (LLRs), from either the symbol detector or the decoder, to aid in CE.

An aspect of this disclosure is a technique to improve CE in NB-NTN.

In accordance with an aspect of the disclosure, a method is provided, which may utilize the structure of scrambled quadrature phase shift keying (QPSK) symbols to perform partial accumulations of repeated symbols without prior CEs or descrambling.

In accordance with another aspect of the disclosure, an iterative CE is provided based on the expectation-maximization maximum likelihood (EM-ML) routine. This estimator uses the structure of the accumulated symbols to iteratively refine the CE with each iteration, enhancing the overall CE performance.

The above approaches improve on previous methods because they avoid the performance degradation associated with conventional scrambling and descrambling operations. The iterative use of partial accumulations optimally combines data repetitions, improving the quality of CEs, which leads to lower block error rates (BLERs) and enhanced overall system performance, especially in low SNR environments typical of satellite communications.

In an embodiment, a method for performing CE in a communication system is provided. The method includes receiving, based on one or more repetitions of a transmitted signal, pilot REs; determining at least two sets of partial accumulations of scrambled data REs over the one or more repetitions; generating one or more LLRs based on a preliminary channel estimate derived from the pilot REs and the partial accumulations of scrambled data REs; generating a secondary channel estimate based on the one or more LLRs; and decoding data using the secondary channel estimate based on the one or more LLRs.

In an embodiment, an electronic device includes a non-transitory storage device storing instructions, and a processor configured to execute the instructions, causing the electronic device to receive, based on one or more repetitions of a transmitted signal, pilot REs over repetitions of a transmitted signal; determine at least two sets of partial accumulations of scrambled data REs over the one or more repetitions; generate one or more LLRs based on a preliminary channel estimate derived from the pilot REs and the partial accumulations of scrambled data REs; generate a secondary channel estimate based on the one or more LLRs; and decode data using the secondary channel estimate based on the one or more LLRs.

### BRIEF DESCRIPTION OF THE DRAWING

In the following section, the aspects of the subject matter disclosed herein will be described with reference to exemplary embodiments illustrated in the figures, in which:

FIG. 1 is a block diagram illustrating a system for iterative CE and decoding, according to an embodiment;

FIG. 2 is a flowchart illustrating a method to perform iterative CE using data aiding, according to an embodiment;

FIG. 3 is a flowchart illustrating a method to perform CE in a communication system, according to an embodiment;

FIG. 4 is a block diagram of an electronic device in a network environment, according to an embodiment; and

FIG. 5 is a block diagram of a system including a UE and a satellite, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

Herein, “RE” may refer to a smallest unit of time-frequency resources used in a communication system for transmitting data, pilots, or control information. Some examples of REs includes individual subcarriers within an orthogonal frequency division multiplexing (OFDM) symbol or a time slot in a time-division multiplexed system.

“Channel estimate” as used herein refers to a calculation or approximation of the channel characteristics, including factors such as gain, phase, and frequency response, used to decode a received signal. Some examples of “channel estimates” are those obtained using pilots to determine the channel's behavior or those derived iteratively using detected data and LLRs in expectation-maximization routines.

“Pilot” as used herein refers to a known reference signal transmitted in a communication system for the purpose of estimating the channel characteristics or synchronizing the transmission. Some examples of “pilots” are the NB reference signals (NRS) used in NB-NTN systems, which are transmitted periodically to enable CE at the receiver.

“Soft information” as used herein refers to probabilistic or confidence-based data that represents the likelihood of a bit being a 0 or 1, rather than a definitive value. Some examples of “soft information” are LLRs and soft-output values from decoders such as the soft-output Viterbi algorithm (SOVA), which are used in iterative decoding processes to improve accuracy.

“LLR” as used herein refers to the logarithm of the ratio of the probabilities that a received bit is a 0 or a 1. In communication systems, LLRs are used to express how likely it is that a particular bit in the received signal corresponds to a 0 or a 1, based on the observed noisy signal. Some examples of “LLRs” are the values produced by decoders in systems that use soft information, such as the output of a Viterbi decoder, or the LLRs used in iterative decoding routines like low-density parity-check (LDPC) decoders.

“Repetition” as used herein refers to the retransmission of the same codeword or symbol across multiple time slots or frames in a communication system. Some examples of “repetition” include transmitting the same data symbol multiple times to improve the effective SNR or reduce the code rate, as may be done in low-SNR environments or systems like NB-NTN.

“Iteration” as used herein refers to a single cycle or step of a computational process where a channel estimate or other parameter is updated based on previous values and newly processed information. Some examples of “iteration” include a step of refining a channel estimate using LLR feedback in an iterative expectation-maximization routine or repeatedly adjusting data decoding until a stopping criterion, such as successful decoding, is met.

The present disclosure introduces an enhanced system and method for CE in NB-NTN using iterative data-aided techniques, which improve upon feed-forward CE, which relies solely on pilot signals for estimating channel gain and phase, followed by symbol detection and decoding. In other methods, once pilots are used for estimation, the process moves forward without revisiting the channel estimate. In at least one embodiment, the proposed method, in contrast, iteratively refines the channel estimate by incorporating soft information derived from the detected symbols, making use of the inherent repetition in NB-NTN of scrambled data REs. This iterative refinement process is particularly useful in NB-NTN environments where the signals are weak, and large path losses are typical due to the long distances involved in satellite communication.

A challenge addressed by one or more of the embodiments described herein is the scrambling of the NB physical downlink shared channel (NPDSCH). Scrambling modifies the transmitted symbols, making it difficult to directly accumulate repeated transmissions to improve the SNR. One or more embodiments overcome this by separating the scrambled symbols into two or more subsets based on their scrambling sequence and performing partial accumulations within each subset. The subsets may be distinct, separate, and/or independent of one another. This method ensures that the accumulation of scrambled data preserves the performance benefits of repetition, even when scrambling distorts the direct comparison of symbols across repetitions.

The CE process can further be enhanced by using an EM-ML estimator, which iteratively refines the channel estimate. The EM-ML estimator benefits from the repeated transmissions typical of NB-NTN, allowing it to continually improve the accuracy of the channel estimate as more data becomes available. This approach is advantageous in low SNR conditions common in satellite communication, where traditional methods underperform. However, the solutions disclosed herein are not limited to satellite communications. By exploiting the structured scrambling in QPSK-modulated symbols, for example, the method maintains robust performance, even in scenarios with weak signals.

Various extensions to the core method are also possible. One extension may involve expanding an NRS-based portion of the estimator by incorporating more pilots over a broader time window, potentially resulting in non-causal channel estimation schemes that introduce processing delay. Filters such as an MA filter or Kalman smoother could be applied in these non-causal schemes to further enhance performance. Another variation may involve combining data-aided estimates across multiple codewords to refine the final channel estimate. This combination could be achieved using various filtering techniques, such as MA filters, infinite impulse response (IIR) filters, or Kalman filters, providing flexibility in optimizing the estimation process.

Accordingly, the final channel estimate (or a “secondary channel estimate”), may also be utilized to optimize subsequent transmissions within the communication system. For example, the secondary channel estimate could be used to configure the transmission channel, including adjustments to modulation, coding rates, or power levels, ensuring that the communication link is optimized for current channel conditions. Additionally, the configured transmission channel may transmit or receive signals with an enhanced communication ability, which improves computational efficiency. By adapting transmission parameters based on a refined channel estimate, the system can enhance overall communication efficiency and reliability, particularly in environments such as low-SNR satellite communications.

Further extending the EM-ML estimator to span multiple codewords is another embodiment disclosed herein. In this case, separate accumulations may be performed for the data REs corresponding to each codeword, enhancing the accuracy of the channel estimate across a broader set of transmissions. Additionally, previously decoded symbols from one codeword could be used as pilots for the subsequent codeword, providing an additional layer of feedback for refining channel estimates. This extension is relevant in time-varying channels, where changes between successive codewords may limit the use of older channel information.

One or more of the embodiments disclosed herein are advantageous in environments where weak signals, frequency offsets (FOs), and high path losses present considerable challenges to reliable communication. While one or more of the embodiments disclosed herein may be tailored to the specific characteristics of NB-NTN, they can also be applied to other communication systems where repetition and scrambling are prevalent, such as terrestrial communication networks involving low-power, wide-area networks.

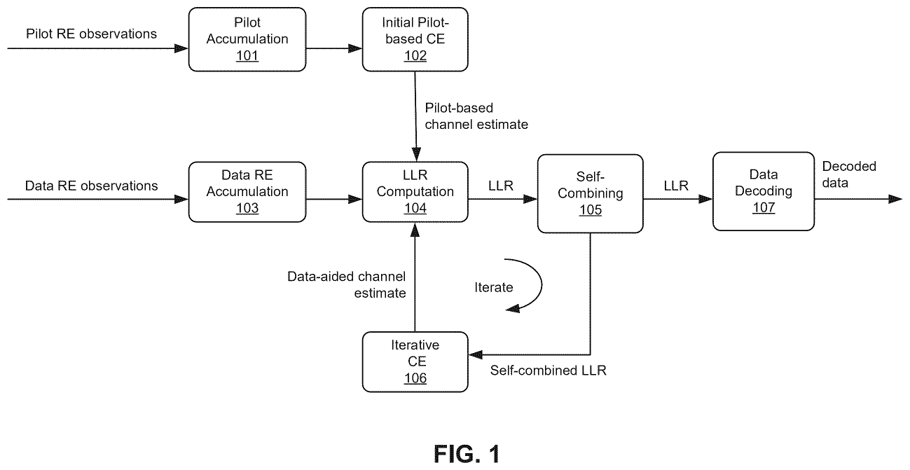

FIG. 1 is a block diagram illustrating a system for iterative CE and decoding using data aiding, according to an embodiment.

The blocks shown in FIG. 1 may be implemented as part of an electronic device that includes hardware components such as a digital signal processor (DSP), memory modules, and/or application-specific ICs (ASICs). For example, LLR computation can be performed by a DSP, while data accumulation and CE may rely on dedicated memory and processing hardware within the device. The device's symbol detection and decoding functions can be handled by specialized circuits or software routines running on the device's central processing unit (CPU) or other processors.

Referring to FIG. 1, pilot RE observations are collected and accumulated across repetitions of the transmitted signal at block 101. Pilots may be known symbols that help the receiver estimate the effects of the channel. By accumulating these pilot signals, the system can improve its ability to estimate the channel, especially in noisy environments.

The accumulated pilot data may be used for generating an initial channel estimate in block 102. This initial estimate may be the system's first approximation of the channel conditions, and is based solely on the pilots. This channel estimate, while useful, may be less accurate when scrambling is applied or when low SNR conditions are present, making further iterative processing necessary.

Simultaneously, data RE observations may be collected and accumulated in block 103. Data REs may carry the information (data symbols) and are subjected to both channel effects and scrambling. Accumulating these data REs can provide additional information that can be used to refine the channel estimate beyond what is possible with pilots alone. This accumulation may be performed for each repetition, allowing for progressive refinement of the channel estimate.

Using both the pilot-based channel estimate and the accumulated data REs, LLRs can be computed in block 104. LLRs may provide soft information about the probability of each bit in the received data being either a 0 or 1. The LLRs allow the system to weigh the confidence in each bit rather than making hard decisions. At this stage, the LLRs can be computed using the initial channel estimate and the partial accumulations of the scrambled data REs.

The computed LLRs may be provided to a symbol detector at block 105, which performs self-combining. Self-combining may involve combining the LLRs across repetitions or slots to enhance the probability estimates. This step may refine the soft information about each bit, increasing the SNR by coherently combining the repeated transmissions.

As part of the iterative process in block 106, the system may use the self-combined LLRs as feedback to refine the channel estimate. This feedback loop may include computing a data-aided channel estimate using both the pilot-based estimate and the information derived from the data RE accumulations. The iterative CE block may use techniques like EM-ML to continually update the channel estimate based on both the data and the pilot signals.

After the iterative CE process, the refined channel estimate can be used to compute new LLRs, which are now based on both the data-aided and pilot-based channel estimates. These updated LLRs can be sent back to the symbol detector for further refinement. The process may repeat through several iterations, with the LLRs and the channel estimate continually improving until a stopping criterion (such as convergence or successful decoding) is met.

At block 107, the decoded data is produced. After several iterations of CE and LLR refinement, the system may decode the transmitted symbols using the final LLRs and channel estimates. This block outputs the final decoded data that corresponds to the transmitted information. By the time the data reaches this block, the accumulated and combined LLRs provide a reliable estimate of the transmitted symbols.

According to various embodiments, CE techniques may use an additive white Gaussian noise (AWGN) channel model for CE evaluation. In this model, the noise added to the signal is assumed to have a normal (Gaussian) distribution with a constant spectral density (referred to as “white” noise) over a wide frequency range. The term “additive” refers to the fact that this noise is added to the transmitted signal as it propagates through the channel. The AWGN model allows for a simplified analysis of the iterative nature of the CE routines, as it avoids having to consider time and frequency channel correlation. Additionally, Doppler shift effect may either be omitted or modeled as a FO, which, for NB-NTN systems, can be a reasonable approximation of the actual channel behavior. This approximation may be justified because NB-NTN typically operates in line-of-sight (LOS) conditions with minimal scattering, as the satellite's elevation can be significantly higher than terrestrial cell towers.

The use of this approximation could further be supported by the fact that NB-NTN might be intended for use cases where TN connectivity is not available, such as in remote or rural areas. NB-NTN might also use NB frequency allocations, typically around 180 kilohertz (kHz), where the assumption of flat fading in the AWGN model could remain appropriate. Furthermore, satellites in NB-NTN environments may not experience scattering, and UE located in remote areas may not encounter rich scattering. Therefore, more complex time-correlation models may be less relevant to NB-NTN (e.g., Jakes model), and the AWGN model could provide a simpler and more suitable representation of the channel.

An appropriate AWGN channel model for NB-NTN may be given by Equation 1:

$$y = hX 1 + n \qquad Equation 1$$

where y is a size K vector for a received signal, h˜ [symbol] (0,1) is the random channel gain, X=diag(x₁, . . . , x_{K}) is a diagonal matrix containing the transmitted symbols, 1 is a size K vector of ones, and n˜ [symbol] .

$$( 0 , diag ( {σ}_{1}^{2} , … , {σ}_{K}^{2} ) )$$

is a size K vector of additive circularly symmetric complex Gaussian noise.

In this model, coherent (maintaining phase alignment between different signals or signal components) combining may be used. For example, let y∈ [symbol] represent a complex column vector of dimension L, arising from the repetition of a scalar complex symbol x. Given the AWGN model, the channel gain h could remain constant across the L repetitions. The vector y could thus be expressed as Equation 2:

$$y = h {1}_{L} x + n \qquad Equation 2$$

where 1_{L} is an L-size column vector of 1's and n˜ [symbol] (0,σ²I_{L}), with I_{L} being a set of indices corresponding to the L×L identity matrix.

By defining U∈ [symbol] as a unitary matrix with its first row as

$$\frac{1}{\sqrt{L}} {1}_{L}^{T} ,$$

the following linear transformation (where “\tilde{y}” signifies a transformed version of y) may be applied without loss of information as shown in Equation 3:

$$\tilde{y} = Uy = hU {1}_{L} x + Un = [ \begin{matrix}\sqrt{L} \\ 0 \\ ⋮ \\ 0\end{matrix} ] hx + \tilde{n} \qquad Equation 3$$

where ñ˜ [symbol] (0,σ²I_{L}). Thus, as shown below in Equation 4:

$$\begin{matrix}\tilde{y} ( 1 ) = \sqrt{L} hx + \tilde{n} ( 1 ) \\ \tilde{y} ( 2 ) = \tilde{n} ( 2 ) \\ ⋮ \\ \tilde{y} ( L ) = \tilde{n} ( L )\end{matrix} \qquad Equation 4$$

Since the noise ñ may include independent components which are jointly independent of the channel coefficient h and x, \tilde{y}(2), . . . , \tilde{y}(L) may include no information about h or x. Therefore, for a purpose of estimating h or detecting x,

$$\tilde{y} ( 1 ) = \frac{1}{\sqrt{L}} {\sum }_{i = 1}^{L} y ( i )$$

(or any scaled version of it, such as

$$\frac{1}{\sqrt{L}} \tilde{y} ( 1 ) = \frac{1}{L} {\sum }_{i = 1}^{L} y ( i )$$

is a sufficient statistic.

$$\frac{1}{\sqrt{L}} \tilde{y} ( 1 ) )$$

may be a simple average of the entries of y and can be associated with coherent combining the L signal components.

NB-NTNs may typically operate at low SNR levels and use repetition to increase the effective SNR and reduce the code rate. Two types of repetition could be employed: symbol repetition within a frame and codeword repetition across frames. Before transmission, data for the physical shared downlink control channel (PSDCH) could be scrambled using a predetermined scrambling sequence known to the receiver. Since the receiver may be able to reverse this operation through descrambling, the scrambling process itself is omitted from this description. However, one of ordinary skill in the art may use known scrambling and/or descrambling techniques.

In the case of repeated symbols, an NB-NTN PSDCH frame could include, for example, 160 data REs, which might include repeated copies of fewer independent symbols. For example, for index k=1, . . . , K, independent symbols xₖ, and [symbol] may be the set of RE indices containing the repeated copies of symbol k. In an AWGN channel, by following the derivation described previously, a sufficient statistic (a statistic (or computed value) that captures all the information needed to estimate a certain parameter) for symbol k could be obtained by coherently combining the received symbols, as shown in Equation 5:

$${\overline{y}}_{k} = \frac{1}{\vert {𝒥}_{k} \vert} {\sum }_{i ∈ {𝒥}_{k}} {y}_{i} = h {x}_{k} + \frac{1}{\vert {𝒥}_{k} \vert} {\sum }_{i ∈ {𝒥}_{k}} {n}_{i} = h {x}_{k} + {\overline{n}}_{k} \qquad Equation 5$$

where n̅ₖ˜ [symbol] (0,σ²/| [symbol] |). Repetition and coherent combining may have the effect of increasing the SNR of the independent symbol by a factor of | [symbol] |.

For repeated codewords, an NB-NTN PSDCH codeword could be repeated multiple times to reduce the code rate and enable decoding at low SNR. For example, r=1, . . . , R may be an index denoting the repetition index of the transmission. In the AWGN channel, a sufficient statistic for symbol k may be obtained by coherently combining the received symbols across repetitions, as shown in Equation 6:

$${{y}^{=}}_{k} = \frac{1}{R} {\sum }_{r = 1}^{R} {\overline{y}}_{k}^{r} = {hx}_{k} + \frac{1}{R} {\sum }_{r = 1}^{R} {\overline{n}}_{k}^{r} = {hx}_{k} + {{n}^{=}}_{k} \qquad Equation 6$$

where

$${{n}^{=}}_{k} ∼ 𝒞𝒩 ( 0 , \frac{{σ}^{2}}{\vert {𝒥}_{k} \vert R} ) .$$

Coherent combining of repeated codewords could increase the SNR by a factor of R. Altogether, symbol and codeword repetition would increase the SNR of the symbols by a factor of | [symbol] |R.

In time-varying channels, the primary factor affecting the channel may be the residual Doppler shift. Since there would be no scattering around the satellite and only limited scattering in the isolated outdoor areas where NB-NTN is applied, a zero Doppler spread could be assumed. If the residual Doppler shift is estimated, coherent combining across symbols and across codeword repetitions may be achieved by applying a phase rotation to the combined symbols, with the phase adjusted proportionally to the estimated Doppler shift and the time spacing between symbols or codewords.

In frequency-selective channels, NB-NTN may not be typically expected to exhibit significant frequency selectivity due to the NB nature of its transmissions. Nevertheless, phase rotation across REs from different subcarriers may need to be estimated, and compensation for this shift could be applied during symbol combining. The estimation of this phase rotation could represent a simpler problem compared to CE itself.

The expectation-maximization techniques such as expectation-maximization-maximum a posteriori (MAP) and EM-ML channel estimators may still be applicable under conditions of symbol and codeword repetition. These estimators may continue to operate under the assumption that coherent combining is performed before LLR computation, and that the appropriate noise variance, such as σ²/(| [symbol] |R), is used when calculating the LLRs (where σ is a measurement of noise).

According to an embodiment, the detector and/or decoder feedback could be used to improve CE. At least three different types of feedback may be considered for this purpose.

One type of feedback could involve soft feedback (or soft information) from a hybrid automatic repeat request (HARQ). Soft feedback from HARQs involves using LLRs generated by the symbol detector or decoder to assist in improving CE. In this process, soft feedback can be used to iteratively refine the channel estimate by feeding probabilistic information back to the CE block.

The generation of LLRs for this feedback may involve processing the currently received symbols. These symbols may be descrambled and then self-combined to form a data stream. This data stream can then be combined with the contents of a HARQ buffer, which stores information from a previous transmission of a repeated codeword.

The combined data, now incorporating both newly received symbols and previously stored information from the HARQ buffer, may then be newly stored in the HARQ buffer. This ensures that the buffer is updated with the latest available information to aid in subsequent retransmissions or iterations.

To generate LLRs, the combined data may undergo further processing. This can include interleaving, rate matching, and scrambling. The LLRs produced from this process may then be fed back to the channel estimator to help refine the CE in subsequent iterations.

When iterative decoding and demodulation (IDD) is enabled, the HARQ buffer contents from the final iteration of a current transmission may be stored in a dedicated HARQ buffer. This stored information is made available for use in the next transmission or retransmission, thereby maintaining a continuous flow of updated soft feedback.

Accordingly, the use of soft feedback from HARQs allows the communication system to iteratively improve CE by using both current and previously processed information. This feedback mechanism improves the accuracy of symbol detection and enhances system performance by reducing errors through the use of soft, probabilistic feedback.

Another type of feedback may involve hard feedback from the decoder. In this mode, the decoder could produce hard decisions, which would then be fed back to the CE block. In the early stages of repetition, the decoder might generate decoding errors; however, a goal could be that some portions of the decoded bits are correct and can still be useful for improving CE.

A third type of feedback may involve soft feedback from the decoder. In this mode, the decoder may generate soft information to be fed back for CE. Several methods could be employed to generate soft feedback, including routines like the SOVA, among others.

According to an embodiment, CE may utilize LLR feedback produced by a symbol processor to generate a conditional probability (e.g., a probability mass function (PMF)). Several CE routines may be employed to make use of this feedback in combination with iterative CE techniques. Regardless of the specific CE routine selected, the CE block may process the available LLRs to compute a PMF p for the received symbols, as shown in Equation 7:

$$Equation 7$$

$$p ( {x}_{j , j + 1} ) ∼ \{ \begin{matrix}{x}_{00} & with probability & [ \frac{1}{1 + exp ( {LLR}_{j} )} ] & [ \frac{1}{1 + exp ( {LLR}_{j + 1} )} ] \\ {x}_{01} & with probability & [ \frac{1}{1 + exp ( {LLR}_{j} )} ] & [ \frac{exp ( {LLR}_{j + 1} )}{1 + exp ( {LLR}_{j + 1} )} ] \\ {x}_{10} & with probability & [ \frac{exp ( {LLR}_{j} )}{1 + exp ( {LLR}_{j} )} ] & [ \frac{1}{1 + exp ( {LLR}_{j + 1} )} ] \\ {x}_{11} & with probability & [ \frac{exp ( {LLR}_{j} )}{1 + exp ( {LLR}_{j} )} ] & [ \frac{exp ( {LLR}_{j + 1} )}{1 + exp ( {LLR}_{j + 1} )} ]\end{matrix}$$

where x_{j,j+1} represents the QPSK symbol associated with the bits indexed by j and j+1.

Accordingly, Equation 7 may be used to “convert” LLRs to probabilities based on whether the bits in x are 0 or 1 for indices j and j+1. Since the sum of x₀₀, x₀₁, x₁₀, and x₁₁ is equal to 1, then if any of the bits have a high probability of being 1, then the remaining bits may be assumed to be 0. In addition, the probability function p may also be denoted as f(x_{r,k}|y_{r-1,k},ĥᵣ₋₁), which may be used as the soft feedback information.

A CE ĥ that can be used in conjunction with the PMF is provided as Equation 8:

$$Equation 8$$

$$\hat{h} = \frac{1}{{K}_{NPDSCH}} {\sum }_{k = 1}^{{K}_{NPDSCH}} {y}_{k} 𝔼 ( \frac{1}{{x}_{k}} ) = \frac{1}{{K}_{NPDSCH}} {\sum }_{k = 1}^{{K}_{NPDSCH}} {y}_{k} {\sum }_{{x}_{k} ∈ Q} \frac{1}{{x}_{k}} p ( {x}_{k} )$$

where p(xₖ) is given by Equation 7 with appropriate indices (j, j+1) for the QPSK symbol k, and ĥ is the estimate of channel coefficient h.

The channel estimator of Equation 8 may not explicitly use the SNR or noise variance as a parameter.

Alternatively, if a noise variance estimate σ² is available (or if another prior estimate of a noise statistic is available), another estimator based on the expectation-maximization MAP routine specialized for AWGN channels can be employed. This estimator is given by Equation 9:

$$Equation 9$$

$$\hat{h} = \frac{1}{( {K}_{NPDSCH} + {σ}^{2} )} {\sum }_{k = 1}^{{K}_{NPDSCH}} {y}_{k} 𝔼 ( \frac{1}{{x}_{k}} ) = \frac{1}{( {K}_{NPDSCH} + {σ}^{2} )} {\sum }_{k = 1}^{{K}_{NPDSCH}} {y}_{k} {\sum }_{{x}_{k} ∈ Q} \frac{1}{{x}_{k}} p ( {x}_{k} )$$

For this scenario, for example, K_{NPDSCH}=160 and at the lowest SNR of interest for NPDSCH of 15 dB, σ²=31. This leads to a minimal difference between the estimators in Equation 8 and Equation 9. Accordingly, the benefits of using noise variance estimation are relatively small in this context.

The 3GPP specification for NB-NTN uses a scrambling process for the NPDSCH in which the scrambling sequence changes with each repetition (non-constant scrambling). When the scrambling sequence varies across repetitions, an accumulation scheme for scrambled data may not apply. This is because accumulation methods typically rely on the assumption that the scrambled symbols remain constant, which is no longer valid when the scrambling sequence changes.

Data scrambling may be applied at the bit level. The scrambling sequence may include a binary sequence where each element is either a 0 or a 1. If the scrambling bit is 1, the corresponding data bit may be flipped; if the scrambling bit is 0, the data bit may remain unchanged.

However, CE routines can operate at the level of complex symbols, often in the QPSK modulated domain. Accordingly, scrambling in the QPSK modulated domain is described below.

In a case in which x is a QPSK modulated data symbol, and s is a bit pair associated with the corresponding bits encoded in x, a scrambling operation is given by Equation 10:

$$scramble ( x , s ) = \{ \begin{matrix}x & if s = ( 0 , 0 ) \\ {x}^{*} & if s = ( 0 , 1 ) \\ - {x}^{*} & if s = ( 1 , 0 ) \\ - x & if s = ( 1 , 1 )\end{matrix} \qquad Equation 10$$

This scrambling operation at the symbol level is non-linear. It cannot be represented merely by multiplying the symbol with a complex scalar, which complicates the process when the symbol has been rotated by the channel h. The resulting signal after the channel has acted upon the scrambled symbol can be expressed as Equation 11:

$$h scramble ( x , s ) + n = \{ \begin{matrix}hx + n & if s = ( 0 , 0 ) \\ hx * + n & if s = ( 0 , 1 ) \\ - hx * + n & if s = ( 1 , 0 ) \\ - hx + n & if s = ( 1 , 1 )\end{matrix} \qquad Equation 11$$

If descrambling were applied to the received symbol without first removing the effects of the channel, the following results may be obtained as shown in Equation 12:

$$descramble ( y ) = descramble ( h scramble ( x , s ) + n , s ) = \{ \begin{matrix}hx + n & if s = ( 0 , 0 ) \\ h * x + n * & if s = ( 0 , 1 ) \\ h * x - n * & if s = ( 1 , 0 ) \\ hx - n & if s = ( 1 , 1 )\end{matrix} \qquad Equation 12$$

In the case of Equation 12, the descrambled data REs produced by this method cannot be directly accumulated to estimate the channel or data, due to the complex relationship between the scrambled symbols and the channel effects. This introduces challenges for CE when non-constant scrambling is used across repetitions, and requires more sophisticated methods to overcome the non-linear scrambling effects before accumulation can take place.

To address the challenge posed by non-constant scrambling across repetitions, an embodiment involves using a preliminary channel estimate, ĥ, such as the one described in Equation 13, below, to remove the channel rotation prior to descrambling.

$$\hat{h} ( 1 ) = \frac{1}{{K}_{NRS}} {\sum }_{k ∈ {C}_{NRS}} {y}_{acc} ( k , R ) \qquad Equation 13$$

where K_{NRS} is used to denote the number of NRS RE's in each slot, C_{NRS} is used to denote the set of NRS REs, and R is the number of repetitions.

Accordingly, at the first iteration of the R^{th} repetition, a simple average of the NRS accumulated RE's may be used to estimate the channel.

The descrambling process, in this case, is performed on the de-rotated symbols, as shown in the following Equation 14:

$$descramble ( \frac{\hat{h} *}{\vert \hat{h} \vert} y , s ) = descramble ( \frac{\hat{h} *}{\vert \hat{h} \vert} h scramble ( x ) + \frac{\hat{h} *}{\vert \hat{h} \vert} n , s ) = \{ \begin{matrix}\frac{\hat{h} *}{\vert \hat{h} \vert} hx + \frac{\hat{h} *}{\vert \hat{h} \vert} n & if s = ( 0 , 0 ) \\ \frac{\hat{h}}{\vert \hat{h} \vert} h * x + \frac{\hat{h}}{\vert \hat{h} \vert} n * & if s = ( 0 , 1 ) \\ \frac{\hat{h}}{\vert \hat{h} \vert} h * x - \frac{\hat{h}}{\vert \hat{h} \vert} n * & if s = ( 1 , 0 ) \\ \frac{\hat{h} *}{\vert \hat{h} \vert} hx - \frac{\hat{h} *}{\vert \hat{h} \vert} n & if s = ( 1 , 1 )\end{matrix} \qquad Equation 14$$

If the estimate ĥ is close to the true channel h, then the accumulation of the resulting descrambled and de-rotated data REs would effectively reduce noise. Following this accumulation process, the channel estimate can be re-rotated to obtain the final accumulated data symbol, expressed as Equation 15:

$${y}_{acc}^{′} ( j ) = \frac{\hat{h}}{\vert \hat{h} \vert} \frac{1}{R} {\sum }_{r = 1}^{R} descamble [ \frac{\hat{h} *}{\vert \hat{h} \vert} y ( j , r ) , s ( j , r ) ] \qquad Equation 15$$

where R is the number of repetitions, j is an index denoting the symbol number (among the K_{NPDSCH} data REs), and s(j,r) is the bit pair of the scrambling sequence used to scramble the data bit pair in symbol j and repetition r. This method can account for the possibility of the scrambling sequence changing across repetitions by performing descrambling prior to accumulation. Data-aided CE can then be performed based on the partially accumulated data REs.

In addition, since

$${y}_{acc}^{′}$$

has already been descrambled, the LLRs used in the data-feedback should be descrambled as well.

The following pseudo-code describes the operation of this CE scheme of descrambling prior to accumulation:

```
if (repetition < R and iteration==1)
      save scrambling sequence in matrix
  save received data REs in matrix
  accumulate NRS pilots
elseif (repetition == R and iteration ==1)
    h_hat = 1/R*average(accumulated NRS pilots)
    compute y′_acc as described in Equation 14 using saved matrices
    compute LLRs using y′_acc and h_hat
    provide LLRs to symbol processor
elseif (repetition == R) %iteration > 1
    obtain LLRs feedback from symbol processor (descrambled)
    h_hat2 = compute data-based channel estimate using LLR feedback
    using Equation 8.
LLRs are descrambled.
    h_hat_new = combine (i.e. weighted sum) h_hat2 and h_hat
    LLR = compute new LLRs using y′_acc and h_hat_new
    Provide LLRs and h_hat_new to symbol processor and other blocks.
end
```

This pseudo-code represents an iterative process for CE and LLR generation, specifically focusing on the handling of repetitions and iterations during signal transmission. The process begins by checking whether the current repetition count is less than R and if it is the first iteration. During this stage, the system saves the scrambling sequence and received data REs into matrices. It also accumulates pilot signals, referred to as NRS pilots, for use in initial (preliminary) CE.

If the current repetition reaches R and it is still the first iteration, the system computes an initial channel estimate ĥ by averaging the accumulated NRS pilots. The system then calculates an accumulated signal

$${y}_{acc}^{′} ,$$

as described in Equation 15, using the previously saved matrices. This accumulated signal, combined with the initial channel estimate ĥ, is then used to generate LLRs, which are provided to the symbol processor for further signal processing.

In subsequent iterations, when the repetition count equals R, the system obtains LLR feedback from the symbol processor. The feedback, which has been descrambled, is used to compute a new data-based channel estimate ĥ₂ using the LLRs and the method described in Equation 8. The system then combines this data-based estimate ĥ₂, with the original pilot-based channel estimate ĥ, using a weighted sum to produce a refined channel estimate, ĥ_{new}. Then, new LLRs are computed based on this updated channel estimate ĥ_{new} and the accumulated signal

$${y}_{acc}^{′} ,$$

and both the new LLKs and the updated channel estimate are provided back to the symbol processor for further iterations.

As explained above, an initial CE may be used to de-rotate the received data REs before accumulation, allowing them to be processed in the descrambled domain. While this method works as expected when the initial channel estimate is accurate, there are cases where a poor initial channel estimate can significantly degrade the quality of the accumulated data. In such scenarios, further processing based on this degraded data is unlikely to succeed, often leading to block errors. To mitigate this, an alternative approach may be applied that enables accumulation of scrambled data REs without relying on a channel estimate.

According to various embodiments, QPSK, a digital modulation scheme defined by the NB-NTN standard, may be used for partial accumulation of scrambled data during CE. QPSK, which encodes data by shifting the phase of a signal into one of four possible states to transmit two bits per symbol, interacts with the scrambling process, which randomizes the transmitted symbols to enhance security and mitigate interference. However, scrambling complicates CE, particularly in noisy environments like NB-NTN. The partial accumulation method disclosed herein is able to use the structure of QPSK-modulated symbols by dividing the received symbols into sets based on their scrambling sequence. These sets may then be partially accumulated over multiple repetitions, correcting for phase shifts introduced by scrambling while reducing the impact of noise. This accumulation allows the system to coherently combine repeated symbols without requiring any channel estimate at the outset. This approach improves the SNR by averaging out noise over repeated transmissions, which enhances the accuracy of the channel estimates.

According to an embodiment, one partial accumulation approach may involve dividing the received data symbols into two sets, labeled A and B, based on the associated scrambling sequence as shown in Equations 16-17, respectively:

$${y}^{A} = \{ y ( j , r ) : s ( j , r ) = ( 0 , 0 ) or s ( j , r ) = ( 1 , 1 ) , r = 1 , … R , j = 1 , … , {K}_{NPDSCH} \} \qquad Equation 16$$

$${y}^{B} = \{ y ( j , r ) : s ( j , r ) = ( 0 , 1 ) or s ( j , r ) = ( 1 , 0 ) , r = 1 , … R , j = 1 , … , {K}_{NPDSCH} \} \qquad Equation 17$$

The scrambling operation within these sets can be described based on Equations 18 and 19:

$$scramble ( x , s ) = \{ \begin{matrix}x & if s = ( 0 , 0 ) \\ - x & if s = ( 1 , 1 )\end{matrix} \qquad Equation 18$$

$$for set A , and$$

$$scramble ( x , s ) = \{ \begin{matrix}x * & if s = ( 0 , 1 ) \\ - x * & if s = ( 1 , 0 )\end{matrix} \qquad Equation 19$$

$$for set B .$$

It follows that within each set, the scrambled symbols are different with respect to sign. The effect of the sign change can be undone based on the knowledge of the scrambling sequence, and the scrambled symbols within each set can be accumulated as follows according to Equations 20-21:

$${y}_{acc}^{A} ( j ) = {\sum }_{r = 1}^{R} 1 ( s ( j , r ) = ( 0 , 0 ) ) y ( j , r ) - 1 ( s ( j , r ) = ( 1 , 1 ) ) y ( j , r ) \qquad Equation 20$$

$${y}_{acc}^{B} ( j ) = {\sum }_{r = 1}^{R} 1 ( s ( j , r ) = ( 0 , 1 ) ) y ( j , r ) - 1 ( s ( j , r ) = ( 1 , 0 ) ) y ( j , r ) \qquad Equation 21$$

and the counts may be determined according to Equation 22-23:

$${K}^{A} ( j ) = {\sum }_{r = 1}^{R} 1 ( s ( j , r ) = ( 0 , 0 ) ) + 1 ( s ( j , r ) = ( 1 , 1 ) ) \qquad Equation 22$$

$${K}^{B} ( j ) = {\sum }_{r = 1}^{R} 1 ( s ( j , r ) = ( 0 , 1 ) ) + 1 ( s ( j , r ) = ( 1 , 0 ) ) \qquad Equation 23$$

where the sum of the count, K^{A}(j)+K^{B}(j)=R (the number of repetitions).

Similar logic can be used to show that the above accumulations are sufficient statistics for channel and data estimation as in the constant scrambling case. Specifically,

$${y}_{acc}^{A} ( j ) and {y}_{acc}^{B} ( j )$$

may serve as sufficient statistics for estimating both the channel and data within their respective sets.

After accumulation, each set may include enough information to estimate the channel. For example, in

$${y}_{acc}^{A} ( j ) ,$$

the expression

$$( 1 / {K}^{A} ( j ) ) {y}_{acc}^{A} ( j ) = hx ( j ) + {\tilde{n}}^{A} ( j )$$

includes information about h and x(j), while in

$${y}_{a c c}^{B} ( j ) ,$$

$$( 1 / {K}^{B} ( j ) ) {y}_{a c c}^{B} ( j ) = h {x}^{*} ( j ) + {\tilde{n}}^{B} ( j )$$

includes information about h and x*(j). Since the noise terms ñ^{A}(j) and ñ^{B}(j) are independent, both accumulations provide independent noisy observations of the channel h.

The information from

$${y}_{a c c}^{A} and {y}_{a c c}^{B}$$

can be combined to estimate the channel. One method may involve using a prior (or initial) channel estimate ĥ to de-rotate

$${y}_{a c c}^{A} and {y}_{a c c}^{B} ,$$

taking the complex conjugate of the de-rotated

$${y}_{acc}^{B} ,$$

and adding it to the de-rotated

$${y}_{a c c}^{A} .$$

However, using a poor channel estimate can degrade performance, and this approach may not be optimal. Instead, modifications to the EM-ML estimator can be used to exploit the benefits of partial accumulation while maintaining optimal performance.

Both accumulations

$${y}_{a c c}^{A} ( j ) and {y}_{a c c}^{B} ( j )$$

corresponds to the same underlying unscrambled symbol x(j), meaning the posterior probabilities for conjugate symbols remain the same. This property can be leveraged to modify the EM-ML estimator for this case. The posterior probability computation and accumulation steps combine the information from both

$${y}_{a c c}^{A} ( j ) and {y}_{a c c}^{B} ( j ) ,$$

which allows the channel estimate to improve iteratively as shown by Equation 24:

$${\hat{h}}^{t} = \frac{1}{J R} {\sum }_{j = 1}^{J} [ {y}_{acc}^{A} ( j ) {\sum }_{{x}_{k} ( j )} {x}_{k}^{*} f ( {x}_{k ( j )} \vert {\overline{y}}_{k ( j )} , {\hat{h}}^{t - 1} ) + {y}_{a c c}^{B} ( j ) {\sum }_{{x}_{k} ( j )} {x}_{k} f ( {x}_{k ( j )} \vert {\overline{y}}_{k ( j )} , {\hat{h}}^{t - 1} ) \qquad Equation 24$$

$$where J = {K}_{NPDSCH} and {\overline{y}}_{k ( j )} is given by Equation 25 :$$

$${\overline{y}}_{k ( j )} = \frac{1}{\vert {𝒥}_{k} \vert R} \frac{{\hat{h}}^{t - 1}}{\vert {\hat{h}}^{t - 1} \vert} {\sum }_{i ∈ {𝒥}_{k}} \{ \frac{{\hat{h}}^{* t - 1}}{\vert {\hat{h}}^{t - 1} \vert} {y}_{a c c}^{A} ( i ) + {[ \frac{{\hat{h}}^{* t - 1}}{\vert {\hat{h}}^{t - 1} \vert} {y}_{a c c}^{B} ( i ) ]}^{*} \} \qquad Equation 25$$

In Equations 24-25, t is the iteration number. In the first iteration, the initial pilot-based channel estimate can be used. Thereafter, the channel estimate obtained in the prior iteration, denoted as ĥ^{t-1}, is used for generating the current estimate ĥ^{t}.

The iterations may continue for as long as desired according to some stopping criterion. The number of iterations may be fixed in advance using a predefined threshold (e.g., by complexity or delay considerations), or a stopping rule may be created. A stopping rule could be based on the change observed across iterations in the channel estimate (i.e., stop if |ĥ^{t}−ĥ^{t-1}|<threshold). A dynamic stopping rule can also be created based on decoding success. Iteration may be continued as long as decoding fails (which can be determined using, for example, a cyclic redundancy check (CRC)). This may encompass running the decoder multiple times, which may incur additional complexity.

Accordingly, embodiments disclosed herein may leverage the simplifications introduced by the partial accumulation of scrambled data, while still resulting in an EM-ML channel estimator, which remains optimal in the EM-ML sense.

The posterior probability function, f(xₖ₍ⱼ₎)|y̅ₖ₍ⱼ₎,ĥ^{t-1}), may be computed using LLR feedback and can be based on the LLRs derived from the combined and descrambled accumulation given in Equation 25. This accumulation is calculated using the channel estimate ĥ^{t-1} from the prior iteration of the routine.

During the first iteration, the channel estimate may be initially based on the accumulated NRSs pilots, as outlined in Equation 13. NRS CE may be the standard CE routine used for NPDSCH NRS pilots. The standard routine may use one-dimensional (1D) frequency-domain (FD)-minimum mean square error (MMSE) CE (e.g., a uniform power delay profile (PDP) or an SNR estimator).

As the iterations proceed, the combination of

$${y}_{a c c}^{A} ( j ) and {y}_{a c c}^{B} ( j )$$

is performed based on a channel estimate ĥ^{t-1}, which is updated with each iteration. The accumulation process refines the channel estimate over successive iterations, with potential improvements at each step.

The accumulations

$${y}_{a c c}^{A} ( j ) and {y}_{a c c}^{B} ( j )$$

should be kept separate during the channel estimate routine of Equation 24 as the channel estimate uses these accumulations independently. This separation ensures that the independent observations of the channel from each set are used effectively in the estimation process.

This partial accumulation of scrambled data scheme may require just twice the buffering capacity of a CE scheme with constant scrambling across repetitions, which is significantly more efficient compared to the buffering requirements of descrambling prior to accumulation. For example, in cases where the number of repetitions R equals 8, the partial accumulation scheme requires four times less buffering than the descrambling prior to accumulation scheme.

The following pseudo-code describes the operation of the CE scheme of partial accumulation of scrambled data:

```
  if (repetition < R and iteration = = 1)
  $update accumulation vectors {y}_{a c c}^{A} and {y}_{a c c}^{B} based on received data and scrambling$
sequence for the current repetition
    accumulate NRS pilots
  elseif (repetition = = R and iteration = = 1)
  h_hat = 1/R*average(accumulated NRS pilots)
  compute vector y̅ⱼ as described in Equation 25 but without intra-slot combining (i.e.
k(j) = j, | [symbol]   | = 1), using h_hat
  compute LLRs using y̅ⱼ and h_hat
  provide LLRs to symbol processor
  elseif (repetition = = R) % iteration > 1
  obtain LLRs feedback from symbol processor (descrambled), which contains intra-slot
combining.
  h_hat2 = compute data-based channel estimate using LLR feedback using Equation
24.
  h_hat_new = combine (i.e. weighted sum) h_hat2 and h_hat
  compute vector y̅ⱼ as described in Equation 25 but without intra-slot combining (i.e.
k(j) = j, | [symbol]   | = 1), using h_hat_new
  LLR = compute new LLRs using updated y̅ⱼ and h_hat_new
  Provide LLRs and h_hat_new to symbol processor and other blocks.
  End
```

This pseudocode describes the operation of the CE scheme based on partial accumulation of scrambled data. The system performs iterative CE and LLR generation while incorporating the concept of partial accumulation to improve signal processing in low-SNR environments.

In the first condition, when the current repetition count is less than R and it is the first iteration, the system updates the partial accumulation vectors

$${y}_{a c c}^{A} and {y}_{a c c}^{B}$$

using the receive data and the corresponding scrambling sequence for the current repetition. These vectors store the accumulated data for symbols that belong to different scrambling sets. This partial accumulation allows the system to manage the scrambling process more effectively and accumulate signal information over multiple repetitions, even though the data has been scrambled. During this stage, the system also accumulates NRS pilots, which will later be used for the initial CE.

When the repetition reaches R during the first iteration, the system calculates the initial channel estimate ĥ by, for example, averaging the accumulated NRS pilots across the repetitions. With this estimate, the system computes the vector y̅ⱼ, as described in Equation 25, without intra-slot combining. That is, the partial accumulation is applied directly to the received data without further combining across slots (k(j)=j, | [symbol] |=1), simplifying the processing at this stage. The vector y̅ⱼ and the initial channel estimate h are then used to generate LLRs, which are passed to the symbol processor.

In subsequent iterations, when the repetition equals R, the system obtains LLR feedback from the symbol processor, which includes data from the intra-slot combining step. The feedback is descrambled and used to compute a new data-based channel estimate ĥ₂ using Equation 24. The new estimate ĥ₂ is then combined with the initial estimate ĥ using a weighted sum, producing an updated channel estimate ĥ_{new}.

The system then recomputes the vector y̅ⱼ using the updated channel estimate ĥ_{new}, again applying partial accumulation without intra-slot combining. This means that the system continues to work with the partial accumulations for each symbol individually, without combining them across slots. The updated vector y̅ⱼ and the refined channel estimate are used to compute new LLRs, which, along with ĥ_{new}, are provided to the symbol processor and other system blocks.

According to various embodiments, several variations of the partial accumulation of scrambled data scheme are possible, each aimed at enhancing CE performance in different scenarios. One potential extension involves modifying the NRS-based portion of the estimator to incorporate more pilots that span either further back into the past or further ahead into the future. In the case of the pilots spanning further ahead into the future, then this extension would introduce delay and result in a non-causal CE scheme. Non-causal CE schemes based on NRS pilots, for example, could be implemented using either an MA filter or a Kalman smoother. These approaches would enhance the quality of the channel estimate by leveraging more pilot information over time.

Another embodiment may involve combining data-aided estimates across different codewords to produce a more refined final estimate. The combination of estimates could be achieved using any suitable filtering method, such as an MA filter, an IIR filter, or a Kalman filter. This approach could aggregate information from multiple codewords to improve the accuracy of the CE.

Additionally, if the introduction of a delay is permissible and the system has sufficient buffering and computational resources, the EM-ML estimator could be extended to span multiple codewords. In this case, separate accumulations may be performed for the data REs corresponding to each of the different codewords. This multi-codeword approach would provide a broader basis for CE, potentially improving the estimate by considering a wider range of signal repetitions and channel conditions over time.

Another possible extension is to use previously decoded symbols from one codeword as pilot symbols for the next codeword. This method may allow the system to apply prior decoded data to improve the channel estimate for subsequent transmissions. In time-varying channels, however, the estimator may need to limit itself to using only a subset of the REs spanned by the previous codeword, as the correlation between codewords may degrade over time due to channel variability.

Additionally, if the channel exhibits frequency selectivity but remains constant over time, the accumulations described in Equations 20-21 may continue to serve as sufficient statistics. In such cases, there is no loss of optimality when storing these accumulations and deferring both CE and decoding to the last repetition. This ensures that the final estimate and decoding are based on the combined information from all repetitions, preserving the quality of the estimation.

In NTN scenarios, the channel may be predominantly LOS with no scattering around the satellite and minimal scattering around the UE. However, a time-varying channel model may also be relevant, where the time variation could be represented as a FO. This FO might arise from Doppler effects or imperfections in frequency tracking. In such cases, the accumulations in Equations 20-21 would need to incorporate a phase adjustment to account for phase rotation between repetitions. This phase adjustment would require an estimate of the FO to correct the phase misalignment between the repetitions before performing further accumulation and CE.

Estimating the phase change between repetitions is a simpler problem than estimating the full channel, particularly in frequency-selective environments. The phase adjustment step focuses only on the phase difference caused by the FO, which simplifies the overall estimation process compared to full CE.

In some cases, an entire set of symbols from the repetitions could be stored, and processing could be deferred until the final R^{th} repetition. At this point, CE and decoding could be carried out for several potential FO candidates, with decoding repeated across different FO values until a successful result is achieved. This method allows for flexibility in handling the FO and ensures that decoding performance can be maximized even under challenging time-varying channel conditions.

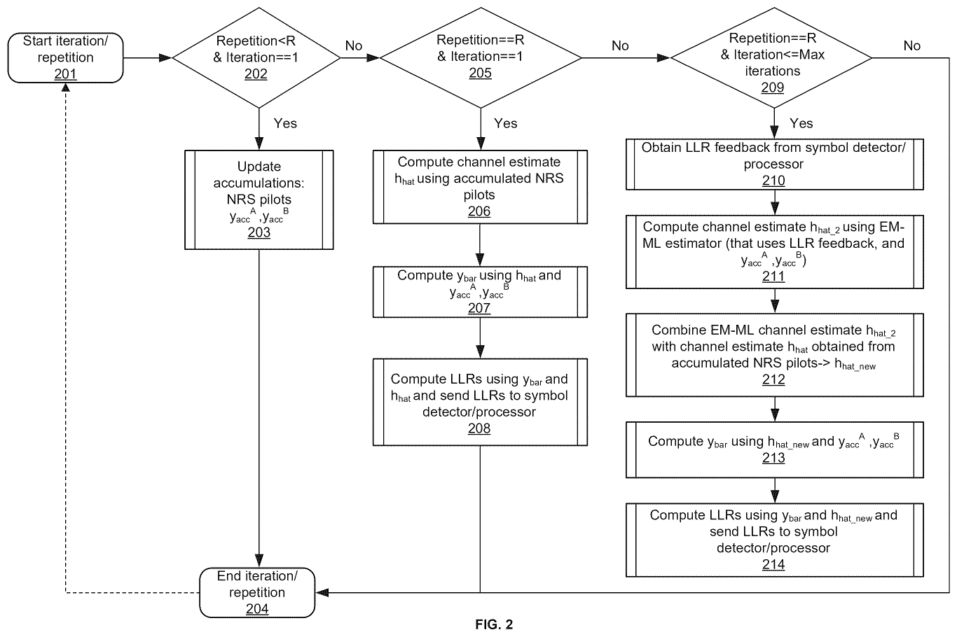

FIG. 2 is a flowchart illustrating a method to perform iterative CE using data aiding, according to an embodiment.

The process illustrated in FIG. 2 may be implemented by an electronic device or system. The device may include one or more processors, memory units, and communication interfaces configured to execute the steps of the method. The electronic device may be connected to a communication network, which can provide access to the data, pilots, and other relevant information required to perform the iterative CE process. Additionally, the device may be part of a larger system or network that facilitates communication with UEs, satellites, or other network components. The system may utilize software, firmware, or hardware modules to handle various aspects of the method, such as accumulation, LLR computation, and symbol detection, and may be capable of scaling or adapting the process to different network conditions or communication protocols.

Referring to FIG. 2, the flowchart illustrates the iterative process of CE and symbol detection in NB-NTN. At step 201, the process initiates. At step 202, it is determined whether the current repetition count is below a defined threshold R (the total number of repetitions), and whether the current iteration is the first iteration. If these conditions are met, the process moves to step 203, where accumulations are updated based on the NRS pilots. This step may use previously received pilot signals to create an initial accumulation, which may serve as the basis for subsequent CE. Once step 203 is complete, then the iteration may end, and the process may repeat at step 204.

In step 205, once the repetition count is equal to R and the current iteration is the first iteration, the system proceeds to step 206, where an initial channel estimate h is computed based on the accumulated NRS pilots. This estimate may serve as the foundation for early stages of the CE process.

At step 207, the system computes y̅ using the current channel estimate ĥ, along with the accumulated values from

$${y}_{a c c}^{A} and {y}_{a c c}^{B} .$$

Accordingly, the accumulated values from the two sets

$${y}_{a c c}^{A} and {y}_{a c c}^{B} ,$$

which were separated based on the their scrambling sequences, may be combined with the refined channel estimate ĥ.

The estimate y̅ may then be used to calculate LLRs in step 208 using ĥ. These LLRs may represent the probability that a given bit in the received data stream corresponds to a 0 or a 1. The LLRs may guide the symbol detection and feedback processes, helping to refine the channel estimate and improve symbol decoding accuracy. The computed LLRs may be sent to the symbol detector/processor for further refinement.

In step 209, the system checks whether the number of repetitions is equal to R and whether the number of iterations is less than or equal to a maximum number of iterations. If the conditions are met, the system progresses to step 210, where LLR feedback is obtained from the symbol detector or processor. This feedback may be useful for further refining the channel estimate, as it includes soft information about the detected symbols that can be used to enhance the overall estimation accuracy.

In step 211, a more refined channel estimate, ĥ₂, is generated using the EM-ML routine. Then, in step 212, the EM-ML channel estimate ĥ₂ is combined with the channel estimate ĥ obtained from NRS pilots. This estimate improves upon the initial NRS-based estimate by incorporating both pilot data and data obtained through symbol detection. The EM-ML process may iteratively refine the channel estimate, increasing its accuracy with each iteration.

In step 213, the system computes the accumulated symbols y using both ĥ_{new} and accumulated values from

$${y}_{a c c}^{A} and {y}_{a c c}^{B} .$$

Once the final symbol is computed, step 214 follows, where new LLRs are generated based on ŷ and ĥ_{new}, and sent to the symbol detector or processor for use in the final decoding process. The symbol detector may use these LLRs to make more accurate decisions about the transmitted symbols, ultimately improving the reliability of the decoded data.

The process may then loop back to step 201 if further iterations are required or if more repetitions are needed. If the conditions for additional iterations or repetitions are not met, the system concludes the process at step 204, where the final channel estimates and decoded symbols are stored or further processed.

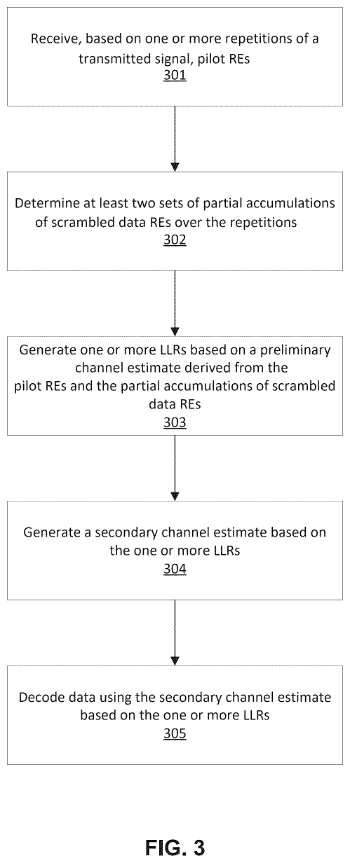

FIG. 3 is a flowchart illustrating a method to perform CE in a communication system, according to an embodiment.

Referring to FIG. 3, the steps of the method may be executed by an electronic device, such as a UE, a base station, or a satellite communication terminal, that is equipped with a processor and memory configured to perform CE and decoding functions. This method provides technical improvements in communication systems by enhancing CE accuracy and decoding reliability, particularly in low-SNR environments typical of satellite and non-terrestrial networks.

In step 301, the method begins with receiving, based on one or more repetitions of a transmitted signal, pilot REs. In this step, the electronic device receives pilot REs, which are known symbols transmitted through the communication channel. These pilots are accumulated (combined) coherently across multiple repetitions of the transmitted signal, allowing the system to average out noise and improve the reliability of the initial channel estimate. Coherent accumulation may refer to the process of summing received signal components in a manner that preserves their phase relationships. Accordingly, the phases of the signal components may be aligned before combining them to improve the SNR.

Next in step 302, the method determines at least two sets of partial accumulations of scrambled data REs over the repetitions (or the one or more repetitions). Data REs may be scrambled to mitigate interference and enhance security. The electronic device may group the scrambled data REs into two sets based on their scrambling sequence and accumulate the REs within each set. This partial accumulation technique may enable the system to correct for scrambling effects and reduce noise while avoiding reliance on a highly accurate initial channel estimate.

The method proceeds in step 303 to generate one or more LLRs based on a preliminary channel estimate derived from the pilot REs and the partial accumulations of scrambled data REs. Using the pilot REs, the system can derive a preliminary channel estimate, which is combined with the partially accumulated data REs to compute LLRs. These LLRs, representing the probability of a bit being 1 or 0, are a form of soft information used to inform subsequent CE and decoding processes.

Following the computation of LLRs, in step 304 the system generates a secondary channel estimate based on the one or more LLRs. This secondary channel estimate can be iteratively refined using the soft feedback provided by the LLRs. The process may involve EM-ML techniques or similar routines to further enhance the accuracy of the channel estimate.

Next, in step 305, the system decodes data using the secondary channel estimate based on the one or more LLRs. In this step, the electronic device may use the refined channel estimate and the computed LLRs to decode transmitted data symbols. This decoding process benefits from the improved CE, resulting in lower BLERs and enhanced communication performance.

Accordingly, the method described in FIG. 3 provides a robust solution for CE and data decoding in challenging communication environments. By incorporating iterative CE, partial accumulation of scrambled data, and the use of LLRs, one or more embodiments disclosed herein are capable of achieving significant improvements in decoding accuracy and overall system efficiency, particularly in scenarios with low SNR or significant scrambling effects.

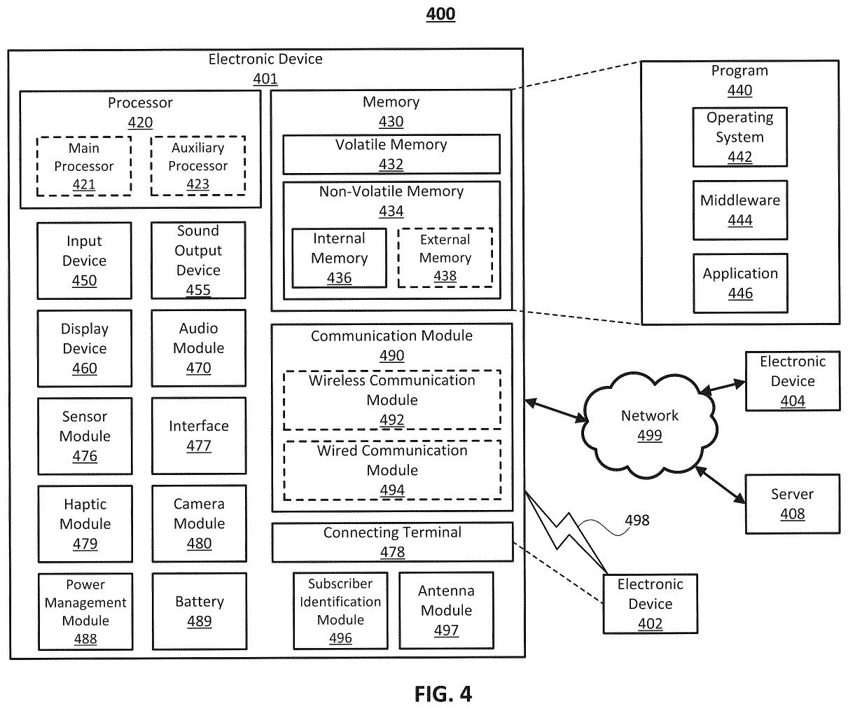

FIG. 4 is a block diagram of an electronic device in a network environment, according to an embodiment.

Referring to FIG. 4, the electronic device 401 includes several specific components used in the operation of the described method. For example, the processor 420 is responsible for executing the software routine that perform the iterative CE, including the accumulation of pilot and data REs, and the computation of LLRs. The memory 430 stores the accumulated data and intermediate channel estimates, ensuring that the iterative process can be carried out effectively over multiple repetitions of the signal. The communication module 490 allows the device 401 to transmit and receive pilot REs and data REs over the network 400, making it possible to collect the necessary information to perform the CE and symbol detection processes.

Accordingly, the processor 420 and memory 430 interact more efficiently to handle the computational load of iterative CE. One or more embodiments disclosed herein reduce the amount of processing power needed by introducing partial accumulations of scrambled data, which allow the device to refine channel estimates without needing to process the full data set at once. This reduces the strain on the processor and memory, enabling faster and more efficient signal processing. Additionally, the system's use of feedback between the symbol processor and the iterative channel estimator provide an improvement in how communication devices can handle noisy or low-SNR environments, such as those found in NB-NTNs.

The electronic device 401 in the network environment 400 may communicate with an electronic device 402 via a first network 498 (e.g., a short-range wireless communication network), or an electronic device 404 or a server 408 via a second network 499 (e.g., a long-range wireless communication network). The electronic device 401 may communicate with the electronic device 404 via the server 408. The electronic device 401 may include a processor 420, a memory 430, an input device 450, a sound output device 455, a display device 460, an audio module 470, a sensor module 476, an interface 477, a haptic module 479, a camera module 480, a power management module 488, a battery 489, a communication module 490, a subscriber identification module (SIM) card 496, or an antenna module 497. In one embodiment, at least one (e.g., the display device 460 or the camera module 480) of the components may be omitted from the electronic device 401, or one or more other components may be added to the electronic device 401. Some of the components may be implemented as a single IC. For example, the sensor module 476 (e.g., a fingerprint sensor, an iris sensor, or an illuminance sensor) may be embedded in the display device 460 (e.g., a display).

The processor 420 may execute software (e.g., a program 440) to control at least one other component (e.g., a hardware or a software component) of the electronic device 401 coupled with the processor 420 and may perform various data processing or computations.

As at least part of the data processing or computations, the processor 420 may load a command or data received from another component (e.g., the sensor module 476 or the communication module 490) in volatile memory 432, process the command or the data stored in the volatile memory 432, and store resulting data in non-volatile memory 434. The processor 420 may include a main processor 421 (e.g., a CPU or an application processor, and an auxiliary processor 423 (e.g., a graphics processing unit (GPU), an image signal processor (ISP), a sensor hub processor, or a communication processor (CP)) that is operable independently from, or in conjunction with, the main processor 421. Additionally or alternatively, the auxiliary processor 423 may be adapted to consume less power than the main processor 421, or execute a particular function. The auxiliary processor 423 may be implemented as being separate from, or a part of, the main processor 421.

The auxiliary processor 423 may control at least some of the functions or states related to at least one component (e.g., the display device 460, the sensor module 476, or the communication module 490) among the components of the electronic device 401, instead of the main processor 421 while the main processor 421 is in an inactive (e.g., sleep) state, or together with the main processor 421 while the main processor 421 is in an active state (e.g., executing an application). The auxiliary processor 423 (e.g., an image signal processor or a communication processor) may be implemented as part of another component (e.g., the camera module 480 or the communication module 490) functionally related to the auxiliary processor 423.

The memory 430 may store various data used by at least one component (e.g., the processor 420 or the sensor module 476) of the electronic device 401. The various data may include, for example, software (e.g., the program 440) and input data or output data for a command related thereto. The memory 430 may include the volatile memory 432 or the non-volatile memory 434. Non-volatile memory 434 may include internal memory 436 and/or external memory 438.

The program 440 may be stored in the memory 430 as software, and may include, for example, an operating system (OS) 442, middleware 444, or an application 446.

The input device 450 may receive a command or data to be used by another component (e.g., the processor 420) of the electronic device 401, from the outside (e.g., a user) of the electronic device 401. The input device 450 may include, for example, a microphone, a mouse, or a keyboard.

The sound output device 455 may output sound signals to the outside of the electronic device 401. The sound output device 455 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 460 may visually provide information to the outside (e.g., a user) of the electronic device 401. The display device 460 may include, for example, a display, a hologram device, or a projector and control circuitry to control a corresponding one of the display, hologram device, and projector. The display device 460 may include touch circuitry adapted to detect a touch, or sensor circuitry (e.g., a pressure sensor) adapted to measure the intensity of force incurred by the touch.

The audio module 470 may convert a sound into an electrical signal and vice versa. The audio module 470 may obtain the sound via the input device 450 or output the sound via the sound output device 455 or a headphone of an external electronic device 402 directly (e.g., wired) or wirelessly coupled with the electronic device 401.

The sensor module 476 may detect an operational state (e.g., power or temperature) of the electronic device 401 or an environmental state (e.g., a state of a user) external to the electronic device 401, and then generate an electrical signal or data value corresponding to the detected state. The sensor module 476 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 477 may support one or more specified protocols to be used for the electronic device 401 to be coupled with the external electronic device 402 directly (e.g., wired) or wirelessly. The interface 477 may include, for example, a high-definition multimedia interface (HDMI), a universal serial bus (USB) interface, a secure digital (SD) card interface, or an audio interface.

A connecting terminal 478 may include a connector via which the electronic device 401 may be physically connected with the external electronic device 402. The connecting terminal 478 may include, for example, an HDMI connector, a USB connector, an SD card connector, or an audio connector (e.g., a headphone connector).

The haptic module 479 may convert an electrical signal into a mechanical stimulus (e.g., a vibration or a movement) or an electrical stimulus which may be recognized by a user via tactile sensation or kinesthetic sensation. The haptic module 479 may include, for example, a motor, a piezoelectric element, or an electrical stimulator.

The camera module 480 may capture a still image or moving images. The camera module 480 may include one or more lenses, image sensors, image signal processors, or flashes. The power management module 488 may manage power supplied to the electronic device 401. The power management module 488 may be implemented as at least part of, for example, a power management IC (PMIC).

The battery 489 may supply power to at least one component of the electronic device 401. The battery 489 may include, for example, a primary cell which is not rechargeable, a secondary cell which is rechargeable, or a fuel cell.

The communication module 490 may support establishing a direct (e.g., wired) communication channel or a wireless communication channel between the electronic device 401 and the external electronic device (e.g., the electronic device 402, the electronic device 404, or the server 408) and performing communication via the established communication channel. The communication module 490 may include one or more communication processors that are operable independently from the processor 420 (e.g., the application processor) and supports a direct (e.g., wired) communication or a wireless communication. The communication module 490 may include a wireless communication module 492 (e.g., a cellular communication module, a short-range wireless communication module, or a global navigation satellite system (GNSS) communication module) or a wired communication module 494 (e.g., a local area network (LAN) communication module or a power line communication (PLC) module). A corresponding one of these communication modules may communicate with the external electronic device via the first network 498 (e.g., a short-range communication network, such as BLUETOOTH™, wireless-fidelity (Wi-Fi) direct, or a standard of the Infrared Data Association (IrDA)) or the second network 499 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 492 may identify and authenticate the electronic device 401 in a communication network, such as the first network 498 or the second network 499, using subscriber information (e.g., international mobile subscriber identity (IMSI)) stored in the subscriber identification module 496.

The antenna module 497 may transmit or receive a signal or power to or from the outside (e.g., the external electronic device) of the electronic device 401. The antenna module 497 may include one or more antennas, and, therefrom, at least one antenna appropriate for a communication scheme used in the communication network, such as the first network 498 or the second network 499, may be selected, for example, by the communication module 490 (e.g., the wireless communication module 492). The signal or the power may then be transmitted or received between the communication module 490 and the external electronic device via the selected at least one antenna.

Commands or data may be transmitted or received between the electronic device 401 and the external electronic device 404 via the server 408 coupled with the second network 499. Each of the electronic devices 402 and 404 may be a device of a same type as, or a different type, from the electronic device 401. All or some of operations to be executed at the electronic device 401 may be executed at one or more of the external electronic devices 402, 404, or 408. For example, if the electronic device 401 should perform a function or a service automatically, or in response to a request from a user or another device, the electronic device 401, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 401. The electronic device 401 may provide the outcome, with or without further processing of the outcome, as at least part of a reply to the request. To that end, a cloud computing, distributed computing, or client-server computing technology may be used, for example.

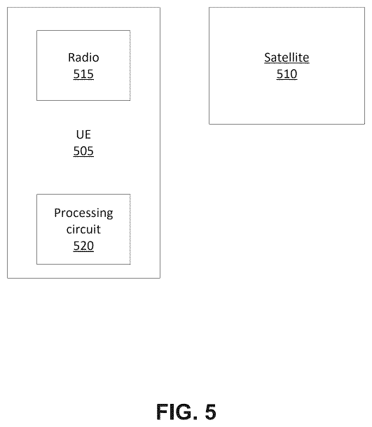

FIG. 5 is a block diagram of a system including a UE and a satellite, according to an embodiment.

FIG. 5 shows a system including a UE 505 and a satellite 510, in communication with each other. The UE may include a radio 515 and a processing circuit (or a means for processing) 520, which may perform various methods disclosed herein, e.g., the method illustrated in FIGS. 3-4. For example, the processing circuit 520 may receive, via the radio 515, transmissions from the network node (satellite) 510, and the processing circuit 520 may transmit, via the radio 515, signals to the satellite 510.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Additionally or alternatively, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple compact discs (CDs), disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method for performing channel estimation in a communication system, the method comprising:
receiving, based on one or more repetitions of a transmitted signal, pilot resource elements (REs);
determining at least two sets of partial accumulations of scrambled data REs over the one or more repetitions;
generating one or more log-likelihood ratios (LLRs) based on a preliminary channel estimate derived from the pilot REs and the partial accumulations of scrambled data REs;
generating a secondary channel estimate based on the one or more LLRs; and
decoding data using the secondary channel estimate based on the one or more LLRs.

2. The method of claim 1, further comprising:
using the one or more LLRs in a symbol detector or processor to generate feedback information; and
iteratively updating the secondary channel estimate based on the feedback information and the partial accumulations in an expectation-maximization maximum likelihood (EM-ML) channel estimator.

3. The method of claim 2, further comprising:
continuing to calculate and generate the one or more LLRs to refine the secondary channel estimate until a stopping criterion is met.

4. The method of claim 3, wherein the stopping criterion is determined by a pre-defined number of iterations or when decoding is successful, as defined by a cyclic redundancy check (CRC).

5. The method of claim 1, wherein the preliminary channel estimate is obtained by, at least one of:
averaging the pilot REs over the one or more repetitions,
applying a moving average filter to the pilot REs,
using a minimum mean square error (MMSE) channel estimator that uses the pilot REs, or
applying a Kalman smoother to the pilot REs.

6. The method of claim 5, wherein the moving average filter or the Kalman smoother is non-causal.

7. The method of claim 3, wherein the feedback information from the symbol detector or processor is generated using intra-slot repetition via self-combining of rate-matched data.

8. The method of claim 3, wherein the feedback from the symbol detector or processor includes soft decoder feedback using a soft-output Viterbi algorithm (SOVA).

9. The method of claim 1, wherein a maximum a posteriori (MAP) channel estimator is applied to generate the one or more LLRs, the MAP channel estimator using a prior estimate of a noise statistic.

10. The method of claim 1, wherein a frequency offset estimate is used to apply a phase rotation to at least one of the pilot REs or the data REs prior to performing the accumulations.

11. An electronic device comprising:
a non-transitory storage device storing instructions, and
a processor configured to execute the instructions, causing the electronic device to:
receive, based on one or more repetitions of a transmitted signal, pilot resource elements (REs);
determine at least two sets of partial accumulations of scrambled data REs over the one or more repetitions;
generate one or more log-likelihood ratios (LLRs) based on a preliminary channel estimate derived from the pilot REs and the partial accumulations of scrambled data REs;
generate a secondary channel estimate based on the one or more LLRs; and
decode data using the secondary channel estimate based on the one or more LLRs.

12. The electronic device of claim 11, wherein the processor is further configured to:
use the one or more LLRs in a symbol detector or processor to generate feedback information; and
iteratively update the secondary channel estimate based on the feedback information and the partial accumulations in an expectation-maximization maximum likelihood (EM-ML) channel estimator.

13. The electronic device of claim 12, wherein the processor is further configured to:
continue calculating and generating the one or more LLRs to refine the secondary channel estimate until a stopping criterion is met.

14. The electronic device of claim 13, wherein the stopping criterion is determined by a pre-defined number of iterations or when decoding is successful, as defined by a cyclic redundancy check (CRC).

15. The electronic device of claim 11, wherein the preliminary channel estimate is obtained by at least one of:
averaging the pilot REs over the one or more repetitions,
applying a moving average filter to the pilot REs,
using a minimum mean square error (MMSE) channel estimator that uses the pilot REs, or
applying a Kalman smoother to the pilot REs.

16. The electronic device of claim 15, wherein the moving average filter or the Kalman smoother is non-causal.

17. The electronic device of claim 13, wherein the feedback information from the symbol detector or processor is generated using intra-slot repetition via self-combining of rate-matched data.

18. The electronic device of claim 13, wherein the feedback from the symbol detector or processor includes soft decoder feedback using a soft-output Viterbi algorithm (SOVA).

19. The electronic device of claim 11, wherein a maximum a posteriori (MAP) channel estimator is applied to generate the one or more LLRs, the MAP channel estimator using a prior estimate of a noise statistic.

20. The electronic device of claim 11, wherein the processor is further configured to use a frequency offset estimate to apply a phase rotation to at least one of the pilot REs or the data REs prior to performing the accumulations.
